(19) United States
(12) Patent Application Publication
(10) Pub. No.: US 2026/0018480 A1
(43) Pub. Date: Jan. 15, 2026

(54) DOUBLE-SIDED MOLDED HIGH-POWER RF SYSTEM IN PACKAGE - THERMAL SOLUTION

(71) Applicant: Qorvo US, Inc., Greensboro, NC (US)

(72) Inventors: MD Hasnine, Richardson, TX (US); Charles E. Carpenter, Orlando, FL (US); Thomas Scott Morris, Lewisville, NC (US)

(21) Appl. No.: 19/252,209

(22) Filed: Jun. 27, 2025

Related U.S. Application Data
(60) Provisional application No. 63/669,891, filed on Jul. 11, 2024.

(51) Int. Cl. H01L 23/34; H01L 23/00; H01L 23/31; H01L 23/535; H01L 25/00

(52) U.S. Cl. CPC H01L 23/34; H01L 23/3135; H01L 23/535; H01L 24/32; H01L 25/00; H01L 24/29; H01L 2224/29139; H01L 2224/29147; H01L 2224/32245

(57) ABSTRACT

Systems and methods are disclosed herein to enable top-side and/or bottom-side cooling for double-sided molded (DSM) packages, thereby providing an enhanced thermal pathway to the ambient environment for densely packed DSM packages.

### RELATED APPLICATIONS

This application claims the benefit of U.S. Provisional Patent Application No. 63/669,891, filed Jul. 11, 2024, the disclosure of which is hereby incorporated herein by reference in its entirety

### FIELD OF THE DISCLOSURE

The present disclosure relates to a Double-Sided Molded (DSM) package and, more specifically, to a DSM package having top-side cooling features and/or bottom-side cooling features.

### BACKGROUND

The use of double-sided molded packages allows for electrical components (e.g., semiconductor dies in which electrical components are implemented) to be assembled on both sides of the substrate. With the rise of telecommunications, 5^{th} Generation (5G) cellular networks, radar applications, defense, aerospace, and more, this technology has experienced substantial growth, enabling greater functionality within a single module through double-sided integration. However, as the electronics industry continues to embrace this technology in high-power radio frequency (RF) applications, thermal challenges have become more apparent due to heat generated by densely packed modules, leading to higher temperatures.

As the gate spacing of Gallium Nitride (GaN) devices decreases, this creates concentrated heat flux, posing critical challenges for device heating and junction temperature rise. This can negatively impact performance and reliability. Heat sinks alone are inadequate for effectively dissipating this concentrated heat flux. In high-power RF packages with Copper (Cu) pillars and solder caps, the ability of the package laminate to dissipate large amounts of heat is limited. This limitation leads to high thermal resistance, ultimately degrading the device's lifetime.

### SUMMARY

Systems and methods are disclosed herein to enable top-side and/or bottom-side cooling for double-sided molded (DSM) packages, thereby providing an enhanced thermal pathway to the ambient environment for densely packed DSM packages. In one embodiment, a DSM package includes a substrate and a first semiconductor die having a front side and a back side, wherein the front-side of the first semiconductor die is electrically and mechanically attached to a top-side of the substrate. The DSM package further includes a top-side heat spreader on the back side of the first semiconductor die and a top mold compound that encapsulates the first semiconductor die and the top-side heat spreader, wherein a back side surface of the top-side heat spreader is exposed through the top mold compound. The DSM package further includes a continuous heat spreader on a top surface of the mold compound such that the continuous heat spreader is in thermal contact with the back-side surface of the top-side heat spreader exposed through the top mold compound. The DSM package further includes a second semiconductor die having a front side and a backside, the front side of the second semiconductor die electrically and mechanically attached to a bottom-side of the substrate.

In one embodiment, the first semiconductor die includes vias that extend from the back side of the first semiconductor die towards the front side of the first semiconductor die, and the vias are filled with a thermally conductive material (e.g., Copper (Cu)).

In one embodiment, the DSM package further includes a bottom-side heat spreader on the back side of the second semiconductor die. In one embodiment, the DSM package further includes a bottom-side mold compound that encapsulates the second semiconductor die and the bottom-side heat spreader, wherein a back side surface of the bottom-side heat spreader is exposed through the bottom mold compound.

Embodiments of a method for fabricating a DSM package are also disclosed. In one embodiment, the method includes attaching a first semiconductor die to a top-side of a substrate, wherein the first semiconductor die has a front side and a back side and the front-side of the first semiconductor die is electrically and mechanically attached to the top-side of the substrate. The method further includes attaching a top-side heat spreader on the back side of the first semiconductor die, applying a top mold compound over the top surface of the substrate such that the top-side mold compound encapsulates the first semiconductor die and the top-side heat spreader, and performing top-side co-grinding such that a back side surface of the top-side heat spreader is exposed through the top mold compound. The method further includes forming a continuous heat spreader on a top surface of the mold compound such that the continuous heat spreader is in thermal contact with the back-side surface of the top-side heat spreader exposed through the top mold compound. The method further includes attaching a second semiconductor die to a bottom-side of the substrate, the second semiconductor die having a front side and a backside wherein the front side of the second semiconductor die is electrically and mechanically attached to a bottom-side of the substrate.

In another embodiment, a DSM package includes a substrate, a first semiconductor die having a front side and a back side, wherein the front-side of the first semiconductor die is electrically and mechanically attached to a top-side of the substrate. The DSM package further includes a second semiconductor die having a front side and a backside, wherein the front side of the second semiconductor die is electrically and mechanically attached to a bottom-side of the substrate, and a bottom-side heat spreader on the back side of the second semiconductor die.

In one embodiment, the DSM package further includes a bottom-side mold compound that encapsulates the second semiconductor die and the bottom-side heat spreader, wherein a back side surface of the bottom-side heat spreader is exposed through the bottom mold compound.

In another embodiment, a method for fabricating a DSM package includes attaching a first semiconductor die to a top-side of a substrate, wherein the first semiconductor die has a front side and a back side and the front-side of the first semiconductor die is electrically and mechanically attached to a top-side of the substrate. The method further includes attaching a second semiconductor die to a bottom-side of the substrate, wherein the second semiconductor die has a front side and a backside and the front side of the second semiconductor die is electrically and mechanically attached to a bottom-side of the substrate. The method further includes attaching a bottom-side heat spreader on the back side of the second semiconductor die.

In one embodiment, the method further includes applying a bottom-side mold compound on the bottom-side of the substrate such that the bottom-side mold compound encapsulates the second semiconductor die and the bottom-side heat spreader. In one embodiment, the method further includes performing bottom-side co-grinding such that a back side surface of the bottom-side heat spreader is exposed through the bottom mold compound.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an example of a top-side die including a semiconductor die for attachment to a substrate (not shown) using Surface Mount Technology (SMT), in accordance with an embodiment of the present disclosure.

FIGS. 2A through 2D illustrate a process for fabricating the top-side die of FIG. 1, in accordance with one example embodiment of the present disclosure.

FIG. 3 illustrates a DSM package including top-side cooling features according to one embodiment of the present disclosure.

FIGS. 4A to 4N illustrate a procedure for fabricating the DSM package of FIG. 3, attaching the heat sink to the top surface of the DSM package, and attaching the DSM package to Printed Circuit Board (PCB), in accordance with one example embodiment of the present disclosure.

FIG. 5 illustrates another embodiment of the DSM package.

FIGS. 6A to 6M illustrate a procedure for fabricating the DSM package of FIG. 5, attaching the heat sink to the top surface of the DSM package, and attaching the DSM package to a PCB, in accordance with one example embodiment of the present disclosure.

FIG. 7 illustrates another embodiment of the DSM package 300 that has both top-side cooling features and bottom-side cooling features, in accordance with an embodiment of the present disclosure.

FIGS. 8A to 8P illustrate a procedure for fabricating the DSM package of FIG. 7, attaching the heat sink to the top surface of the DSM package, and attaching the DSM package to a PCB, in accordance with one example embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Systems and methods are disclosed herein to enable top-side and/or bottom-side cooling for double-sided molded (DSM) packages, thereby providing an enhanced thermal pathway to the ambient environment for densely packed DSM packages. In some embodiments, a DSM package having top-side cooling is provided, wherein the DSM package includes any one or more of the following aspects:
A top-side heat-spreader attached on a top-side of each semiconductor die (e.g., each Gallium Nitride (GaN) die) during assembly using a thermally conductive sinter material such as, e.g., sintered Copper (Cu). The top-side heat-spreader is formed of a thermally conductive material such as Silicon Carbide (SiC), Silicon (Si), or Cu. Preferably, the top-side heat-spreader is formed of a material compatible with co-grinding.
A continuous heat-spreader on a top surface of the top-side of the DSM package over exposed top surfaces of the heat-spreader(s) fabricated on the top-side(s) of the semiconductor die(s). The continuous heat-spreader is preferably formed of a metal such as Cu. An Electroless Nickel-Immersion Gold (ENIG) surface finish is formed on a top surface of the continuous heat-spreader to provide a top surface that is highly compatible with a heat sink that may be subsequently attached to the DSM package.
For at least one of the semiconductor dies, vias are formed on a top-side of the semiconductor die and filled with a thermally conductive material such as, e.g., Cu.

In some embodiments, a DSM package having bottom-side cooling is provided, wherein the DSM package includes a bottom-side heat-spreader attached to a bottom-side of a semiconductor die (e.g., a GaN die) during assembly using a thermally conductive sinter material such as, e.g., sintered Cu. The bottom-side heat-spreader is formed of a thermally conductive material such as SiC, Si, or Cu. Preferably, the bottom-side heat-spreader is formed of a material compatible with co-grinding. In addition, the bottom-side heat-spreader is also preferably compatible with a surface finish technology such as Electroless Nickel-Immersion Gold (ENIG). Thus, in one preferred embodiment, the bottom-side heat-spreader is formed of Cu.

In some embodiments, a DSM package having both top-side cooling and bottom-side cooling is provided. For the top-side cooling, the DSM package includes any one or more of top-side cooling aspects described above (i.e., any one or more of the following: top-side heat spreader(s), continuous heat-spreader, and/or filed vias on the top-side of the semiconductor die(s)). For bottom-side cooling, the DSM package includes the bottom-side heat spreader described above.

In one embodiment, a backside via-filled die with a heat spreader attached to it, utilizing double-sided molded packaging technology, is provided. This enables the addition of a continuous heat spreader on a top-surface of the die, facilitating top-side cooling and significantly lowering the device junction temperature. A process for fabricating a DSM package begins with a GaN (or Gallium Arsenide (GaAs) high-power radio frequency (RF) Cu Post (CuP) Flip-Chip (FC) die having Cu-filled vias formed into a top-surface of the die. There may be one or more such dies. Next, the FC die(s) is (are) packaged conventionally, such as print flux, employing a flip chip on a laminate substrate. Then, a discrete SiC heat spreader is attached to the top-side (also referred to as the “back-side”) of each die using high thermal conductivity sintering material after Surface Mount Technology (SMT) reflow followed by compression molding, and post-mold cure. Subsequently, the module undergoes bottom-side die-attach, compression molding, and cure. The module is then flipped and co-grinding is performed to expose the top-side surface(s) of the heat spreader(s). After co-grinding, a Titanium (Ti)/Cu seed layer, a continuous copper heat spreader, and Nickel (Ni)/Gold (Au) metallization (also referred to herein as a ENIG finish layer) are deposited on the top-surface of the module using an electroplating process. This process will ensure a highly compatible top surface for subsequent direct attachment of a heat sink to the top-side of the DSM package. The module will then undergo bottom-side co-grinding to expose bottom-side solder ball(s). Finally, laser ablation and reflow are performed to increase the solder ball standoff height, allowing the customer to attach the component to a Printed Circuit Board (PCB) and heat sink. This continuous heat spreader provides an efficient path for top-side cooling heat extraction in next-level assembly.

In addition or alternatively, employing the assembly concept described earlier, a high-power die can also be affixed to the bottom-side of the laminate substrate. In this case, in one embodiment, a discrete copper heat spreader is attached to a bottom-side of this bottom-side die. Co-grinding the bottom-side is performed to reveal both the copper heat spreader and Cu posts for providing electrical (and mechanical) connection to a coined PCB. The bottom-side Cu heat spreader (and the Cu posts) can then be connected to the coined PCB utilizing solder paste. This method increases the bottom-side die heat spreading performance through a Cu heat spreader and coined PCB thus enabling bottom-side heat transfer.

Embodiments of the present disclosure utilize vias in a top-side of a semiconductor die (e.g., GaN or GaAs die) that are filled with a thermally conductive material, which in the example embodiments described herein is Cu. Note that the filled vias are optional (i.e., not necessary in all embodiments). Embodiments of the present disclosure also relate to providing a DSM package with a heat spreader attached to the top-side (i.e., backside) of the die using sintering material. Components are attached on both the top and bottom-sides of a substrate (e.g., a laminate substrate) using double-sided molded packaging technology. Additionally, an electroplating process is used to deposit a continuous heat spreader over the top-surface of the DSM package, allowing for the extraction of heat from the top-side of the module through the heat-spreader(s) and continuous heat-spreader.

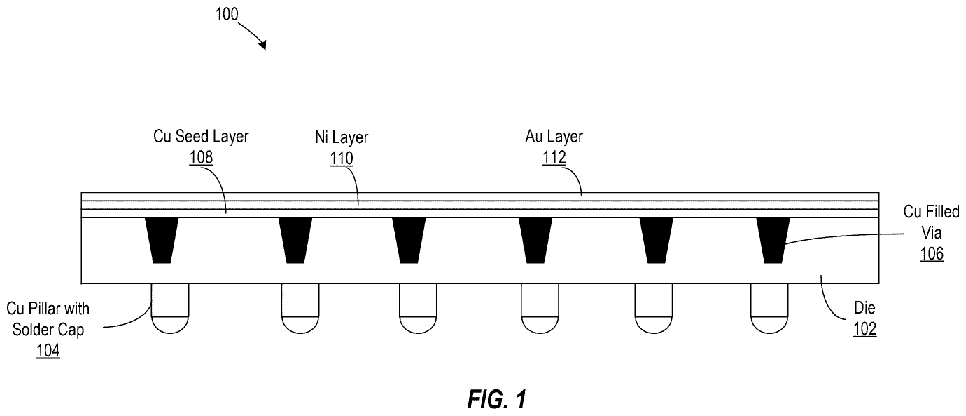

FIGS. 1 to 6M relate to DSM package having top-side cooling in accordance with various embodiments of the present disclosure. More specially, FIG. 1 illustrates an example embodiment of a top-side die 100 including a semiconductor die 102 for attachment to a substrate (not shown) using SMT. The top-side die 100 may also be referred to herein as a “top-side die module” to be clear that it include components in addition to the semiconductor die 102. The semiconductor die 102 is preferably a GaN die or a GaAs die. Further, the semiconductor die 102 preferably includes one or more high-power RF components. As illustrated, the semiconductor die 102 includes Cu pillars 104 having solder caps formed on a bottom surface of the semiconductor die 102. The Cu pillars 104 serve to provide electrical connections between the electrical (e.g., RF) component(s) implemented in the semiconductor die 102 and a substrate (not shown) on which the semiconductor die 102 is mounted using SMT.

Multiple Cu-filled vias 106 extend from a top surface of the semiconductor die 102 toward (but not reaching) the bottom surface of the semiconductor die 102. Note that while Cu is used in the example embodiments described herein, the vias 106 may be filled with any thermally conductive material (Cu, Au, Silver (Ag), or the like). Preferably, this thermally conductive material has a thermal conductivity of at least 3 Watts per Meter-Kelvin (W/mK) or in the range of 3 to 500 W/mK. The Cu-filled vias 106 provided improved heat spreading performance. However, it should again be noted that that the Cu-filled vias 106 are optional.

In the illustrated example, a Cu seed layer 108, a Ni layer 110, and an Au layer 112 are formed on the top surface of the semiconductor die 102. The Cu seed layer 108 is preferably 0.1 to 0.5 microns thick, the Ni layer 110 is preferably 2-10 microns thick, the Au layer 112 is preferably 0.1 to 2 microns thick. Note that the Cu seed layer 108, Ni layer 110, and Au layer 112 are only an example. Additional or alternative layer(s)/material(s) may be used. In general, any number of layers of materials may be used to provide a wettable or sinter-able surface and thermally conductive interface between the semiconductor die 102 and a corresponding top-side heat spreader (not shown) attached to the top-surface of the semiconductor die 102 (specifically to the top surface of the Au layer 112 in the illustrated example).

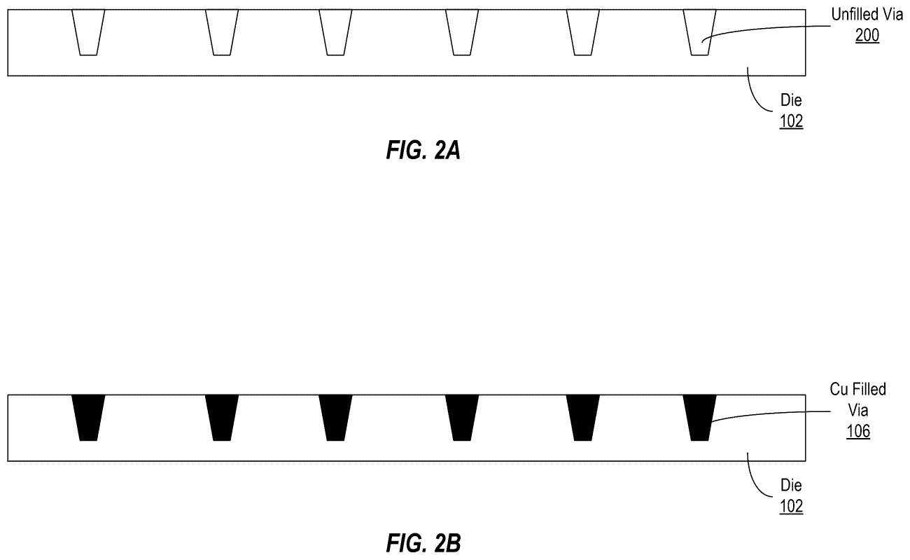

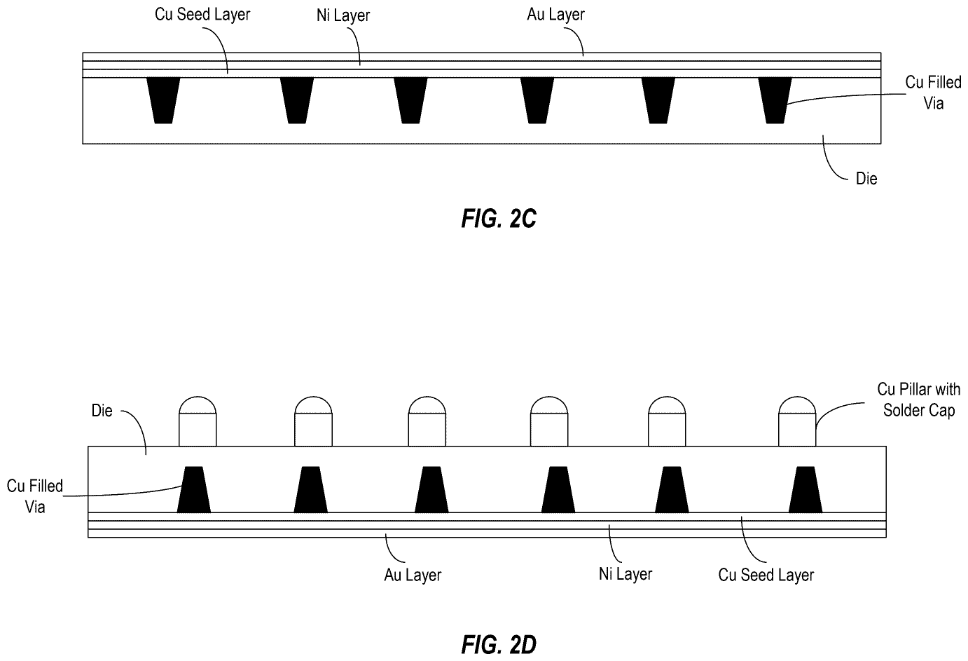

FIGS. 2A through 2D illustrate a process for fabricating the top-side die 100 of FIG. 1, in accordance with one example embodiment of the present disclosure. As illustrated in FIG. 2A, the process begins with the semiconductor die 102 and unfilled vias 200. As noted above, the semiconductor die 102 is preferably a high-power GaN or GaAs FC die with unfilled vias 200 in the backside (or top-side) of the semiconductor die 102. As illustrated in FIG. 2B, the unfilled vias 200 are filled with, in this example, Cu, to provide the Cu-filled vias 106, which enhance the heat spreading performance of the semiconductor die 102. As illustrated in FIG. 2C, following the filling process, a continuous copper seed layer (i.e., the Cu seed layer 108) is deposited on the top-side (i.e., the backside) of the semiconductor die 102, followed by the Ni layer 110 and flash Au coating (i.e., the Au layer 112) to ensure compatibility with the sintered material used for attachment of a top-side heat spreader (not shown). All via filling and seed layer deposition can be accomplished during the wafer-level process. As illustrated in FIG. 2D, the Cu pillars 104 having solder caps are formed on the bottom-side (i.e., the front side) of the semiconductor die 102. This process facilitates attachment of a heat spreader to the top-side (i.e., the backside) of the semiconductor die 102 die using sintering material, thus circumventing the high-temperature reflow and void formation issues that can occur when the vias are left unfilled during Gold-Tin (AuSn) solder attachment. Utilizing sintering material allows for heat spreader attachment at a lower temperature (e.g., ˜200° C.) compared to the very high temperatures required for AuSn solder attachment (e.g., ˜310° C.).

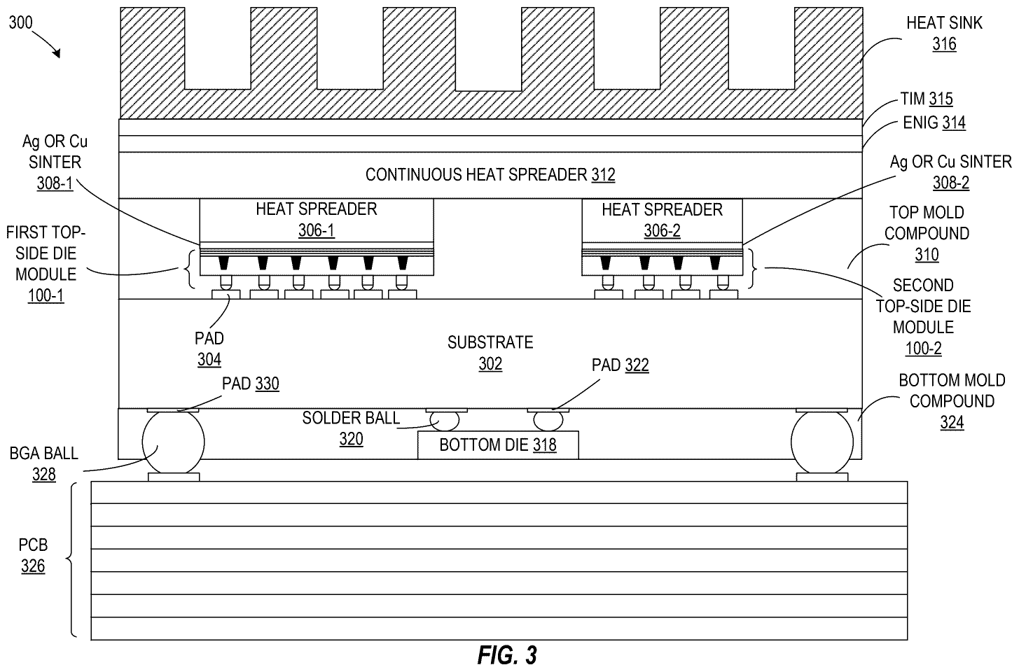

FIG. 3 illustrates a DSM package 300 including top-side cooling features according to one embodiment of the present disclosure. In this example, the DSM package 300 includes two top-side dies 100, denoted as a first top-side die 100-1 and a second top-side die 100-2. However, the DSM package 300 may include any number of one or more top-side dies 100. As illustrated, the first top-side die 100-1 is attached to a top surface of a substrate 302 using SMT technology. More specifically, the Cu pillars 104 with solder caps on the front-side of the first top-side die 100-1 are attached to corresponding electrically conductive contact pads 304 on the top surface of the substrate 302. Likewise, the Cu pillars 104 with solder caps on the front-side of the second top-side die 100-2 are attached to corresponding electrically conductive contact pads 304 on the top surface of the substrate 302. In this manner, the dies in the first and second top-side dies 100-1 and 100-2 are electrically (and mechanically) attached to the top surface of the substrate 302.

The DSM package 300 includes a first top-side heat spreader 306-1 attached to a backside surface of the first top-side die 100-1 via sinter material 308-1, which in this example is either an Ag or Cu sinter material. Likewise, the DSM package 300 includes a second top-side heat spreader 306-2 attached to a backside surface of the second top-side die 100-2 via sinter material 308-2, which in this example is either an Ag or Cu sinter material. The top-side heat spreaders 306-1 and 306-2 are formed of a thermally conductive material such as, e.g., SiC, Si, or Cu. The thickness of the top-side heat spreaders 306-1 and 306-2 depends on module power, but as an example is in the range of and including 100 to 600 microns. The first and second top-side dies 100-1 and 100-2 and the first and second top-side heat spreaders 306-1 and 306-2 are encapsulated by a top mold compound 310.

A continuous heat spreader 312 is formed (e.g., via sputtering and subsequent electroplating of a desired thermoelectric material such as, e.g., Cu) on the top-surface of the DSM package 300 over exposed back-side surfaces of the first and second top-side heat spreaders 306-1 and 306-2. Preferably, the continuous heat spreader 312 extends over the entire top surface of the DSM package 300 or at least a majority of the top surface of the DSM package 300. The continuous heat spreader 312 is formed of a thermally conductive material, which in one preferred embodiment is Cu. A minimum thickness of the continuous heat spreader 312 is in a range of and including 50 to 300 microns.

An ENIG layer 314 is formed on a top surface of the continuous heat spreader 312. The ENIG layer 314 is thermally conductive and serves to passivate the surface of the continuous heat spreader 312 to provide a surface that is highly compatible with a thermal interface material 315 used for attachment of heat sink 316. In one example embodiment, the ENIG layer 314 includes a Gold (Au) layer having a thickness in the range of and including 0.1 to 2 microns and a Nickel (Ni) layer having a thickness in the range of and including 2 to 10 micros. While not illustrated, a thermal interface material (TIM) may be applied during next-level assembly, such as during module attach to PCB, prior to heat sink placement.

The DSM package 300 also includes a bottom-side semiconductor die 318 attached to the bottom-side of the substrate 302. More specifically, in this example, a front-side of the bottom-side semiconductor die 318 is electrically (and mechanically) attached to the bottom-side of the substrate 302 via solder balls 320 and corresponding electrical contact pads 322 on the bottom surface of the substrate 302. The bottom-side semiconductor die 318 is encapsulated by a bottom mold compound 324.

The DSM package 300 is attached (electrically and mechanically) to a PCB 326 using, in this example, BGA balls 328 and corresponding contact pads 330 on the bottom surface of the substrate 302.

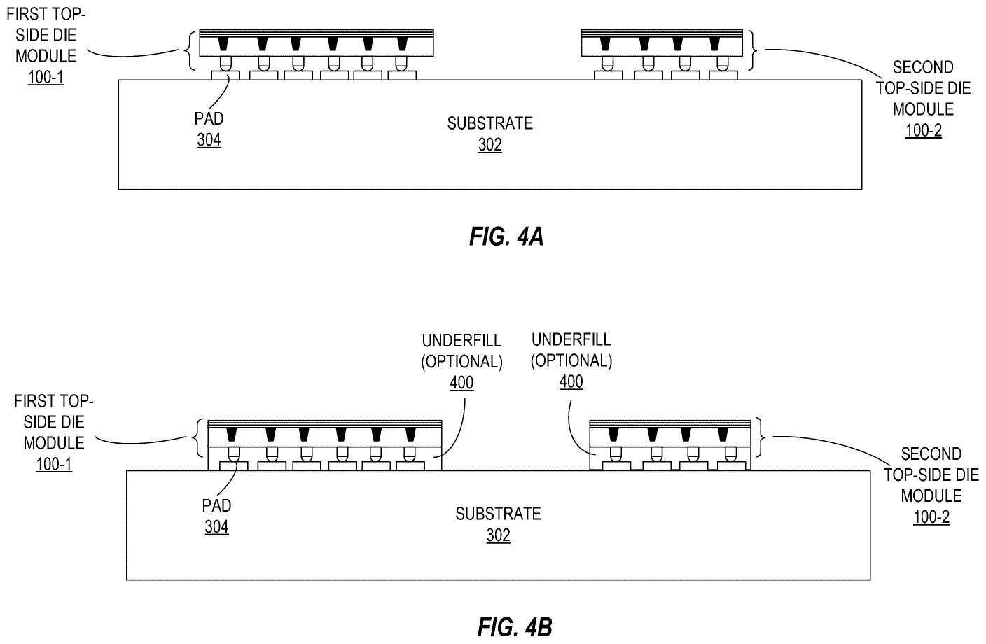

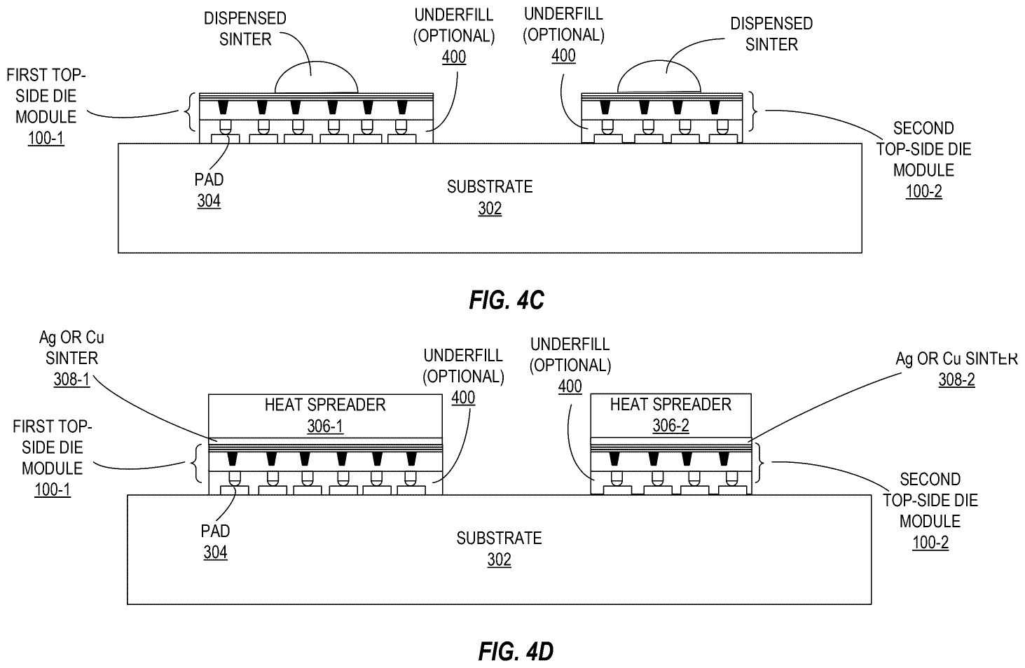

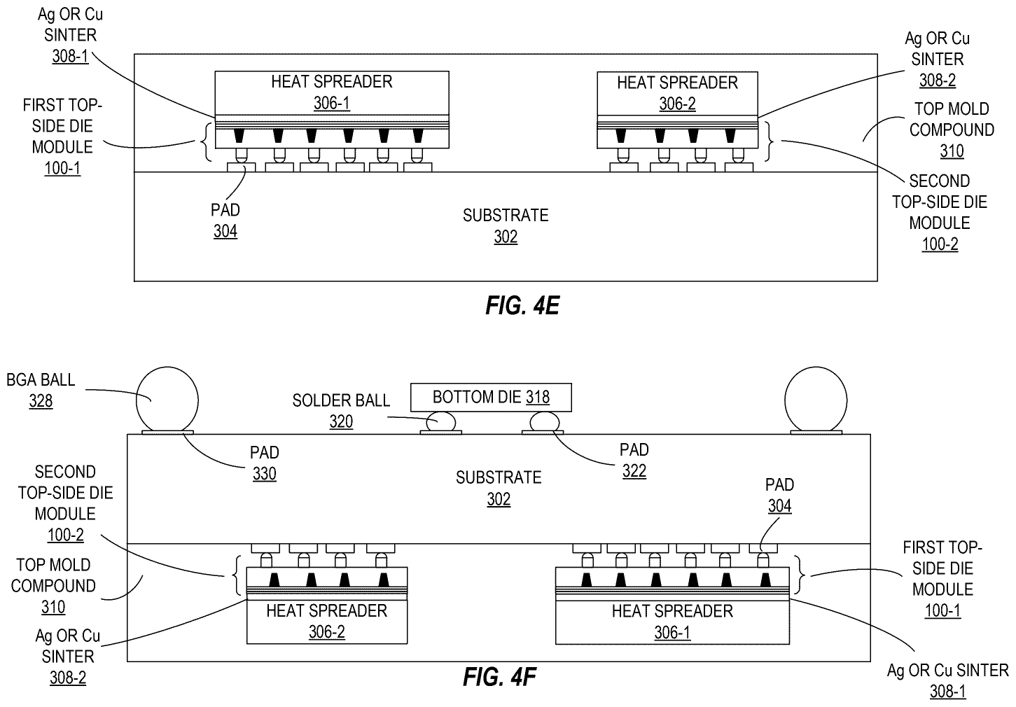

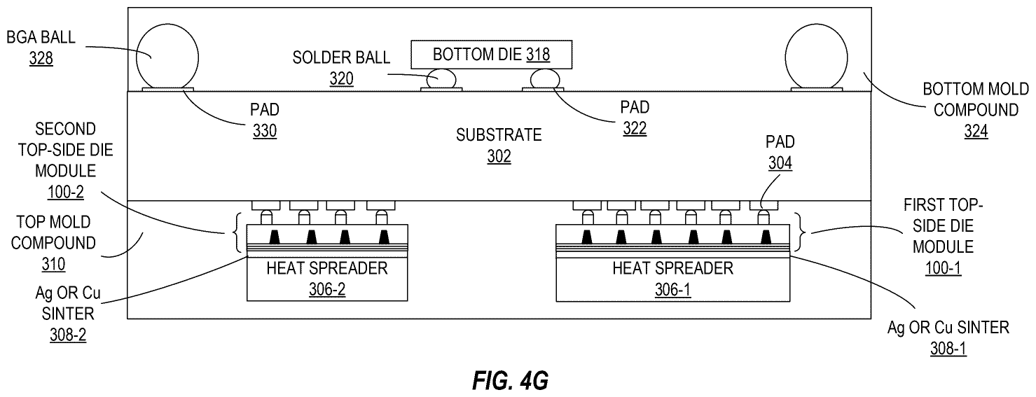

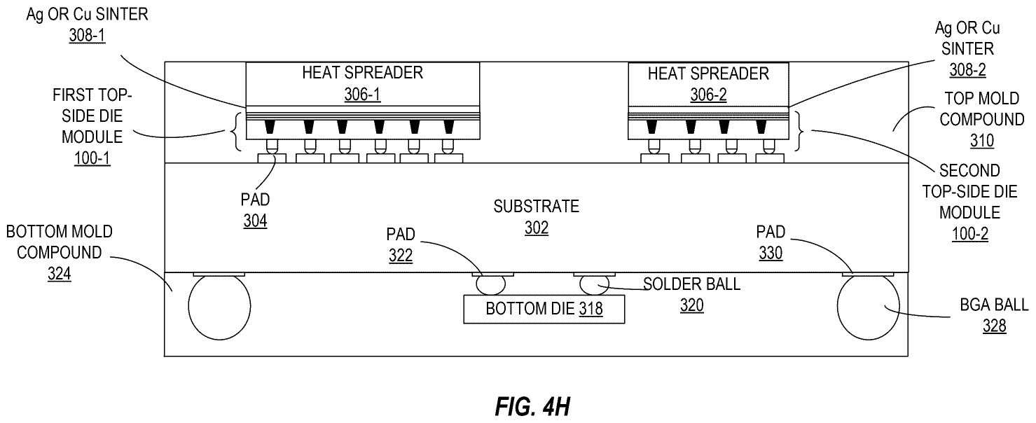

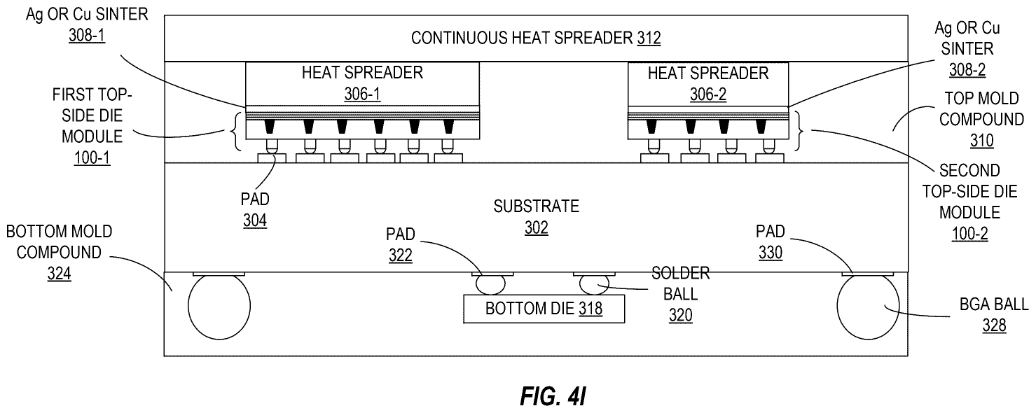

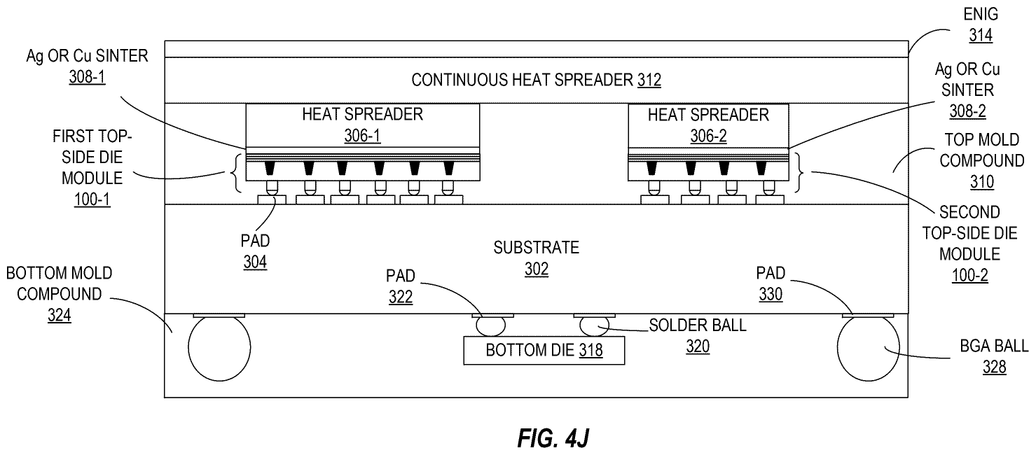

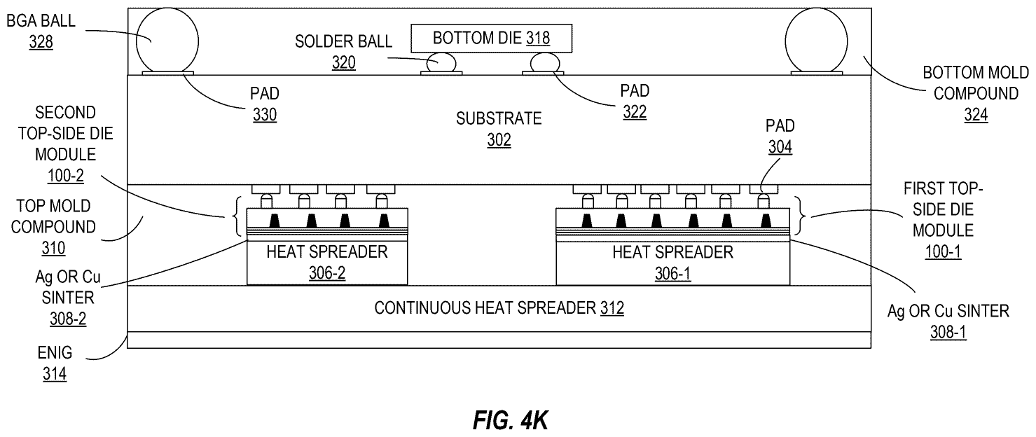

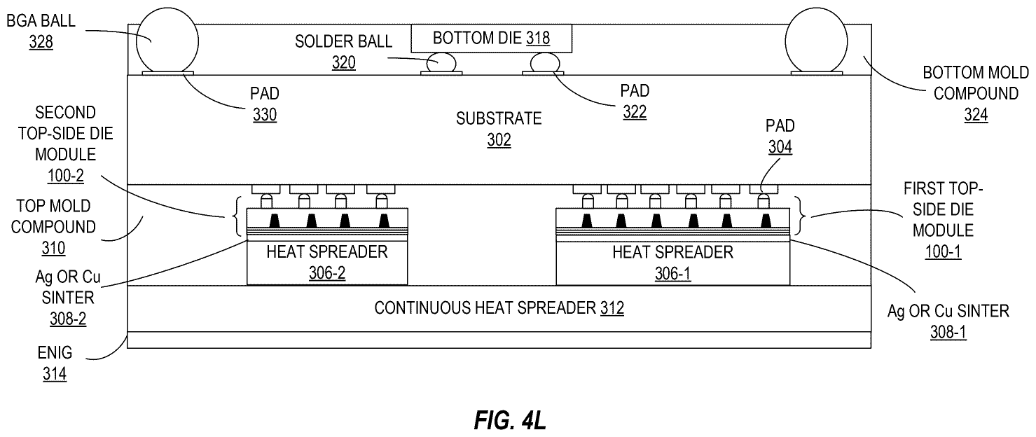

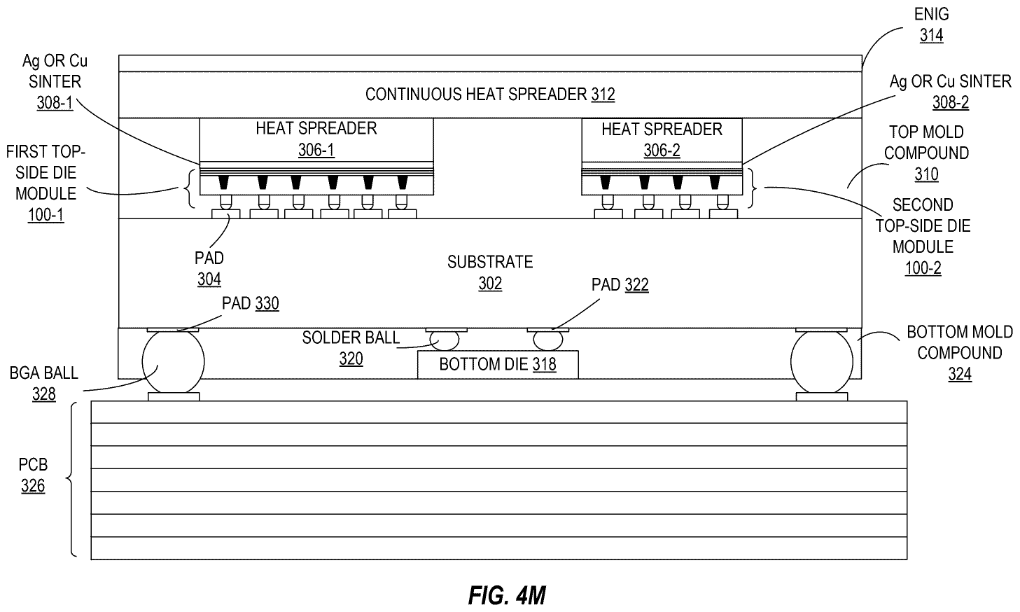

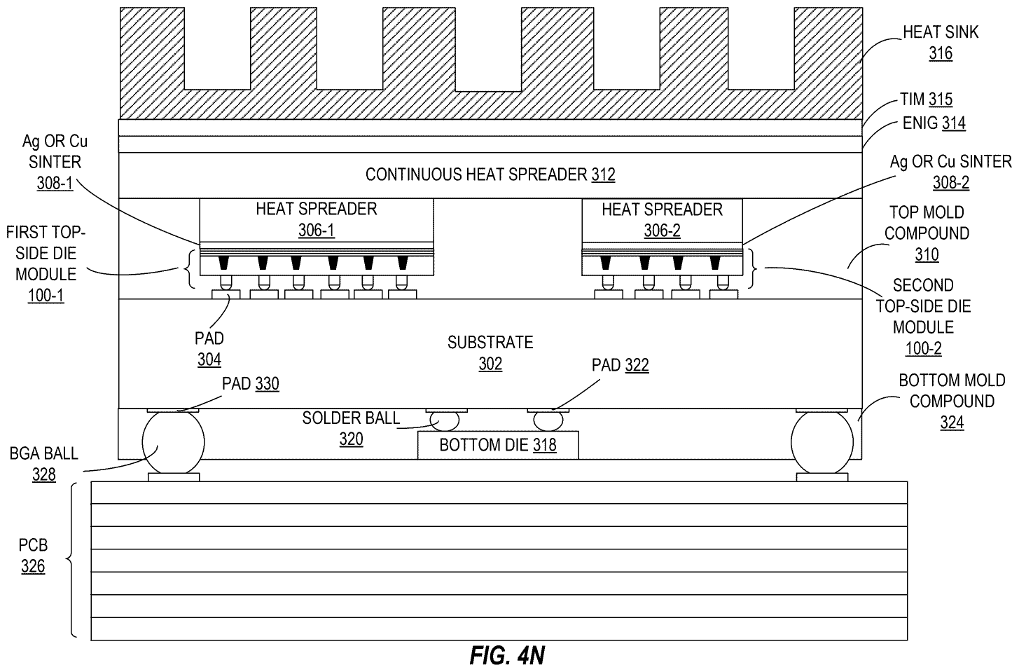

FIGS. 4A to 4N illustrate a procedure for fabricating the DSM package 300 and attaching the heat sink 316 and attaching the DSM package 300 to the PCB 326, in accordance with one example embodiment of the present disclosure. It should be noted that not all steps of the procedure are required. Further, part of the procedure (e.g., the steps illustrated by FIGS. 4A to 4L) may be performed by one entity (e.g., a manufacturer of the DSM package 300) and other parts of the procedure (e.g., the steps illustrated by FIGS. 4M and 4N) may be performed by another entity (e.g., a customer that purchased the DSM package 300 from the manufacturer).

As illustrated in FIG. 4A, the process begins by attaching the first and second top-side semiconductor die modules 100-1 and 100-2 to the top surface of the substrate 302. In this example, high-power devices are implemented in the first and second top-side semiconductor die modules 100-1 and 100-2, and the first and second top-side semiconductor die modules 100-1 and 100-2 are preferably GaN or GaAs dies. Further, in this example, both of the first and second top-side semiconductor die modules 100-1 and 100-2 include the Cu-filled vias 106; however, again, the Cu-filled vias 106 are optional. The first and second top-side semiconductor die modules 100-1 and 100-2 may be attached to the top surface of the substrate 302 through a series of steps including, e.g., die pick, flux dipping, reflow, and cleaning, as will be appreciated to those of ordinary skill in the art of SMT. This approach will allow attachment of the top-side heat spreaders 306-1 and 306-2 after SMT reflow.

After completion of the attachment of the first and second top-side semiconductor die modules 100-1 and 100-2, optionally, an underfill material 400 may be applied as shown in FIG. 4B. In other words, before attachment of the top-side heat spreaders 306-1 and 306-2, a capillary underfill material 400 can be dispensed and cured to protect the solder caps of the Cu pillars 104 during sintered material curing process. The underfill process is optional because the cure temperature of sintered material is below the melting temperature of the solder caps/bumps.

Next, as illustrated in FIG. 4C, the sinter material 308-1 and 308-2 is dispensed on a top surface (i.e., the back-side surface) of the first and second top-side semiconductor die modules 100-1 and 100-2. The top-side heat spreaders 306-1 and 306-2 are placed on the top surfaces (i.e., the back-side surfaces) of the first and second top-side semiconductor die modules 100-1 and 100-2 over the dispensed sinter material 308-1 and 308-2 and the module is cured at low temperature (e.g., ˜200 degrees C.), as illustrated in FIG. 4D.

Following this, the module (in this context “module” refers to the part of the DSM package 300 that has been fabricated at the current point in the procedure) undergoes top compression molding and post-mold cure, thereby forming the top mold compound 310, as illustrated in FIG. 4E.

Subsequently, the module undergoes bottom-side die and ball attach, compression molding, and cure, as illustrated in FIG. 4F and FIG. 4G.

The module is then flipped, and top-side co-grinding is performed to expose the top-side (i.e., the backside) of the top-side heat spreaders 306-1 and 306-2, as illustrated in FIG. 4H. As illustrated in FIGS. 4I and 4J, a Ti/Cu seed layer (optional, not shown), the continuous heat spreader 312 (e.g., Cu layer), and the ENIG layer 314 (e.g., Ni/Au metallization) are deposited on the top surface of the module, e.g., using electroplating process(es).

As illustrated in FIG. 4K, the module then undergoes bottom-side grinding to expose the BGA balls 328. Finally, laser ablation and reflow is performed to increase the BGA ball standoff height as illustrated in FIG. 4L, which allows attachment of the DSM package 300 to the PCB 326 and the heat sink 316 (via TIM 315), as illustrated in FIGS. 4M and 4N. The continuous heat spreader 312 provides an efficient path for top-side cooling heat extraction using the heat sink 316.

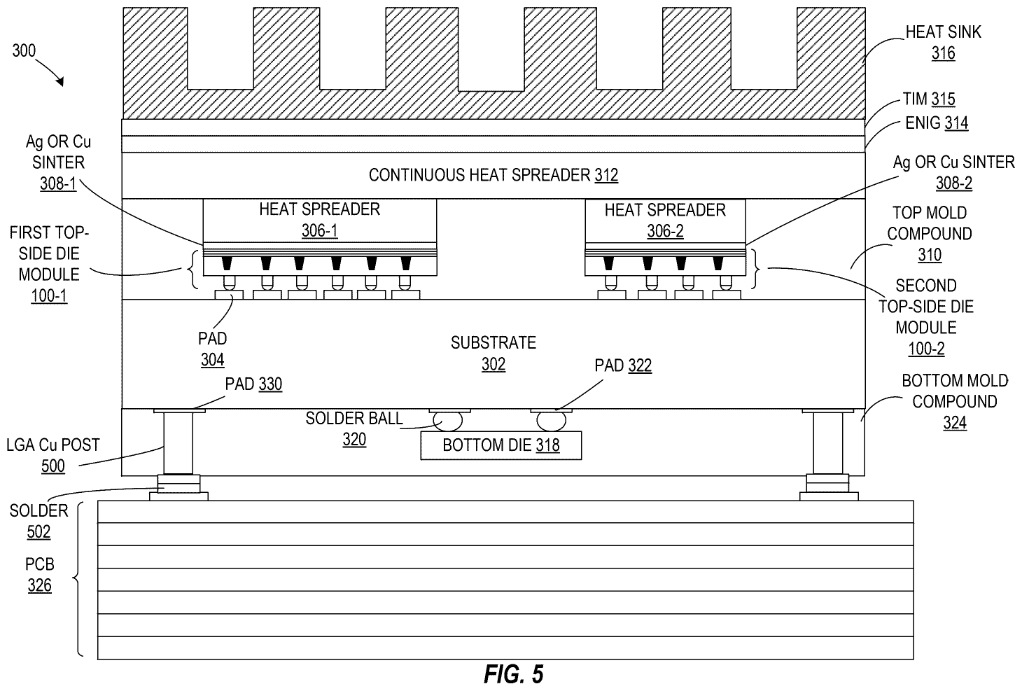

FIG. 5 illustrates another embodiment of the DSM package 300 but where the DSM package 300 (i.e., the substrate 302) is attached to the PCB 326 using a Land Grid Array (LGA) of Cu posts 500 that are attached (electrically and mechanically) to the contact pads 330 on the bottom surface of the substrate 302 at one end and to respective contact pads on the top surface of the PCB 326 using solder 502 (e.g., solder paste) at the other end. Otherwise, the embodiment of the DSM package 300 shown in FIG. 5 is the same as that shown in FIG. 3.

In one embodiment, the substrate 302 arrives with the Cu posts 500 pre-attached to its bottom-side. To prevent damage to these pre-attached Cu posts 500, the bottom-side process is, in one embodiment, conducted first during component attachment.

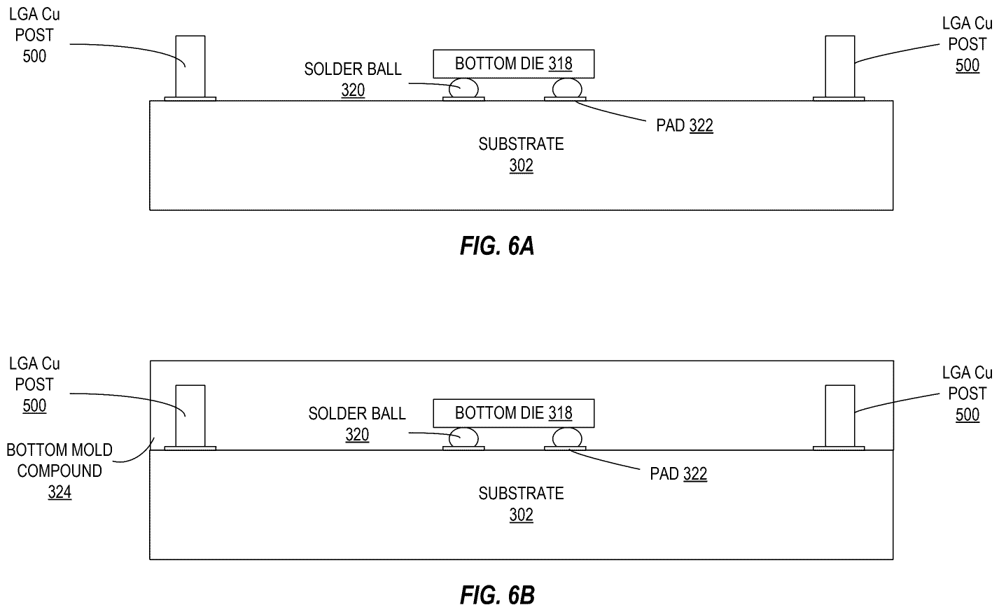

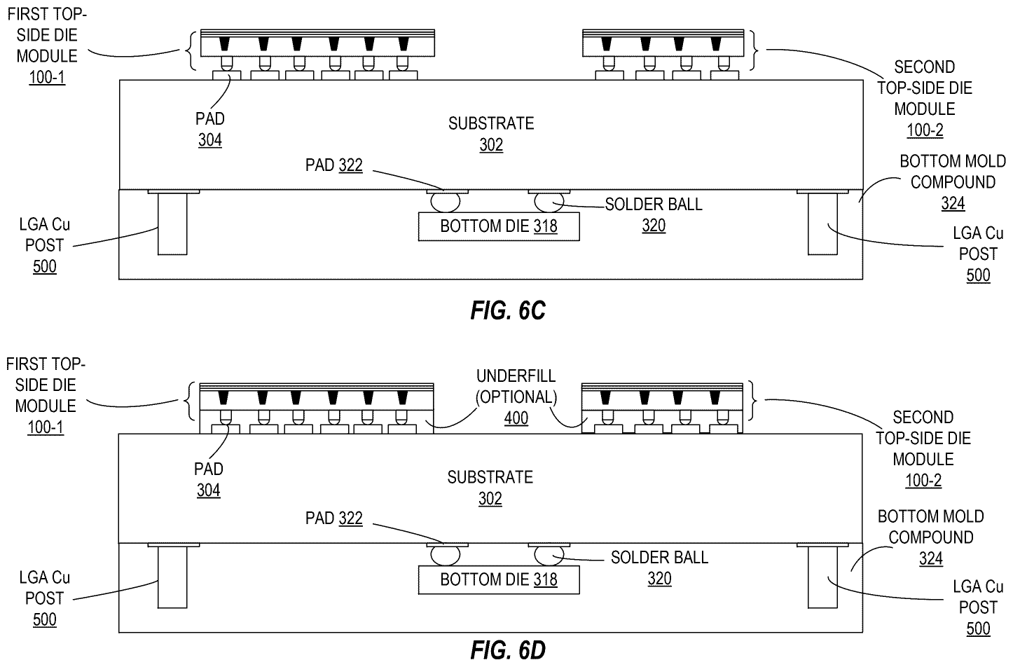

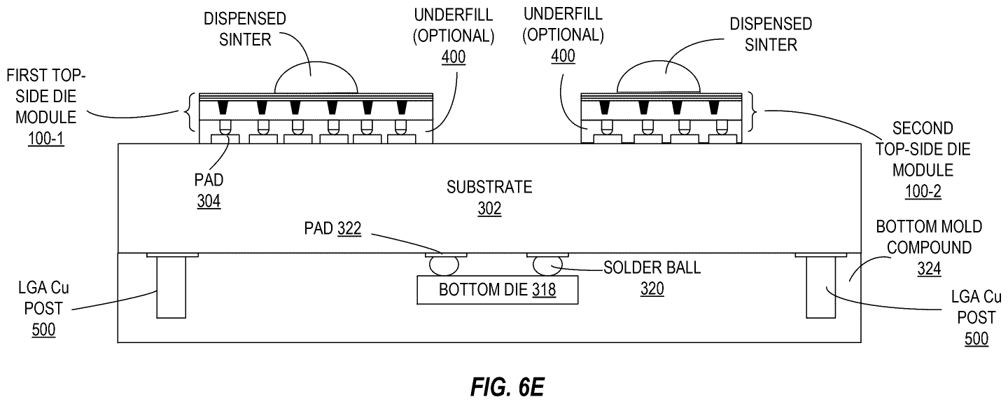

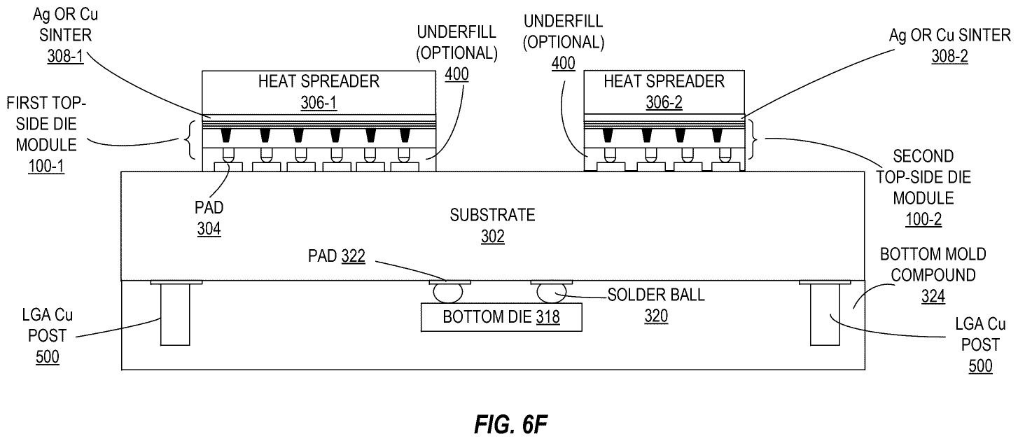

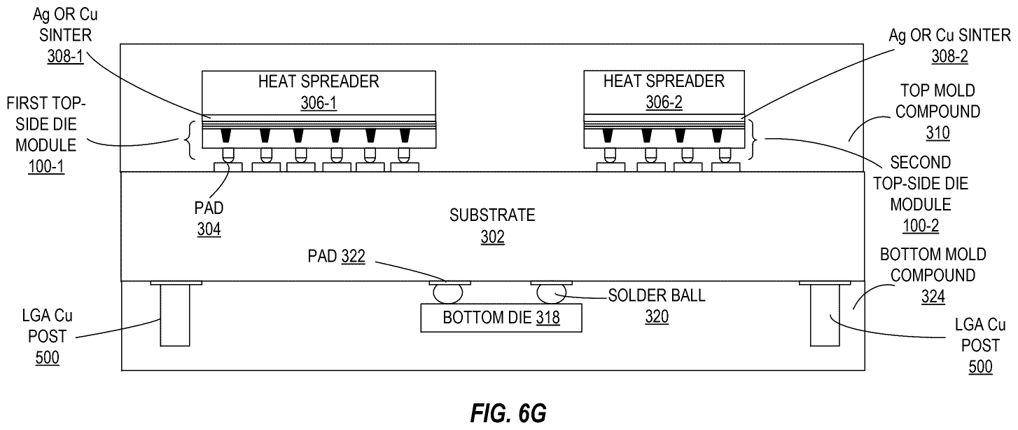

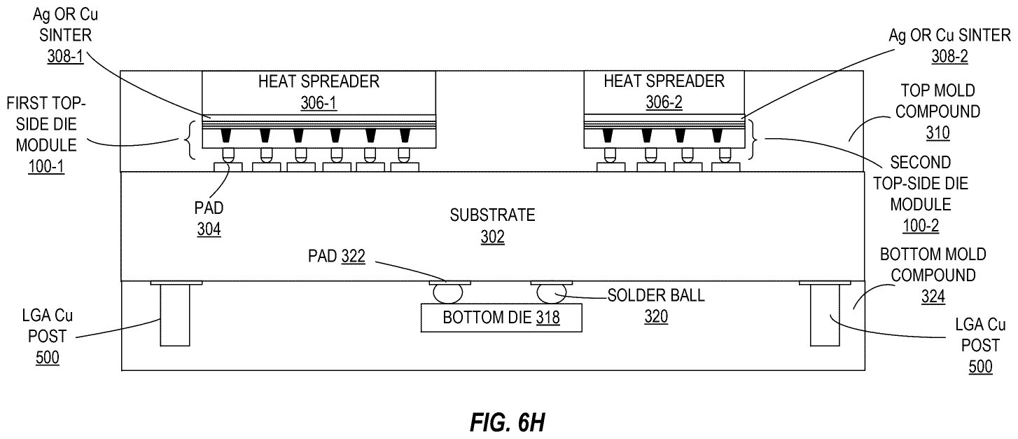

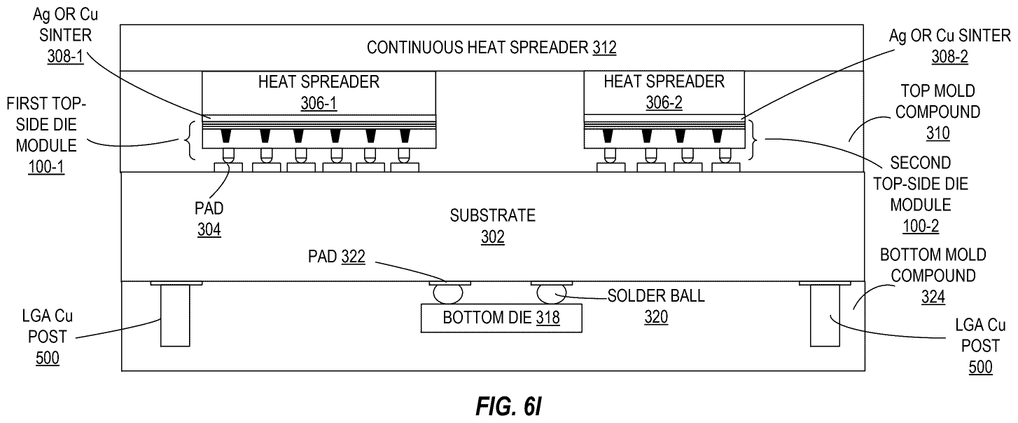

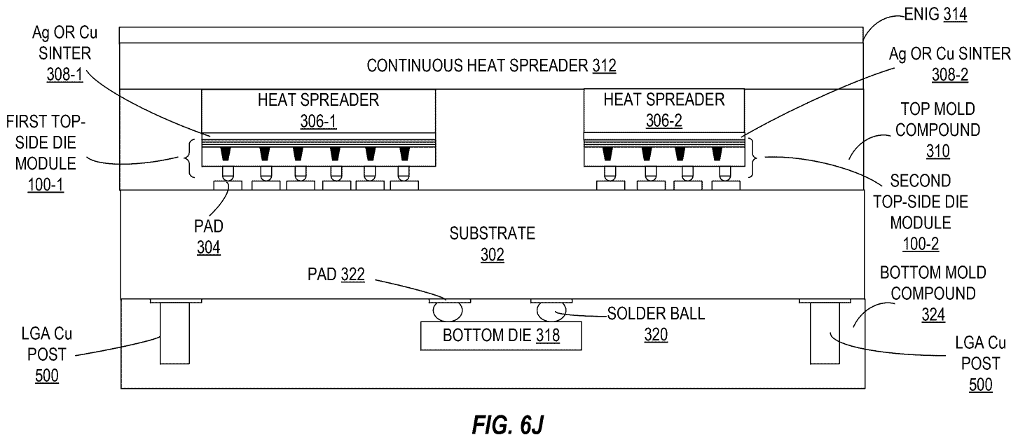

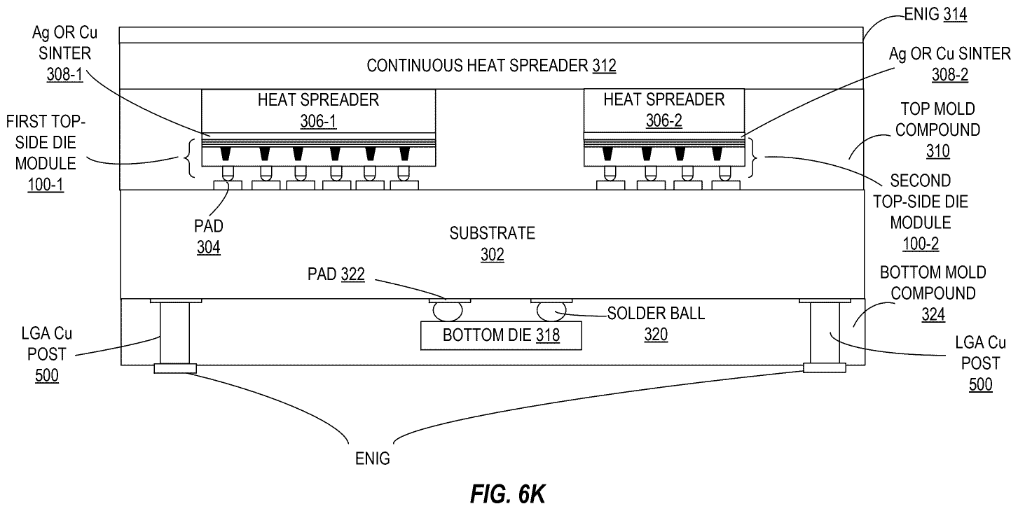

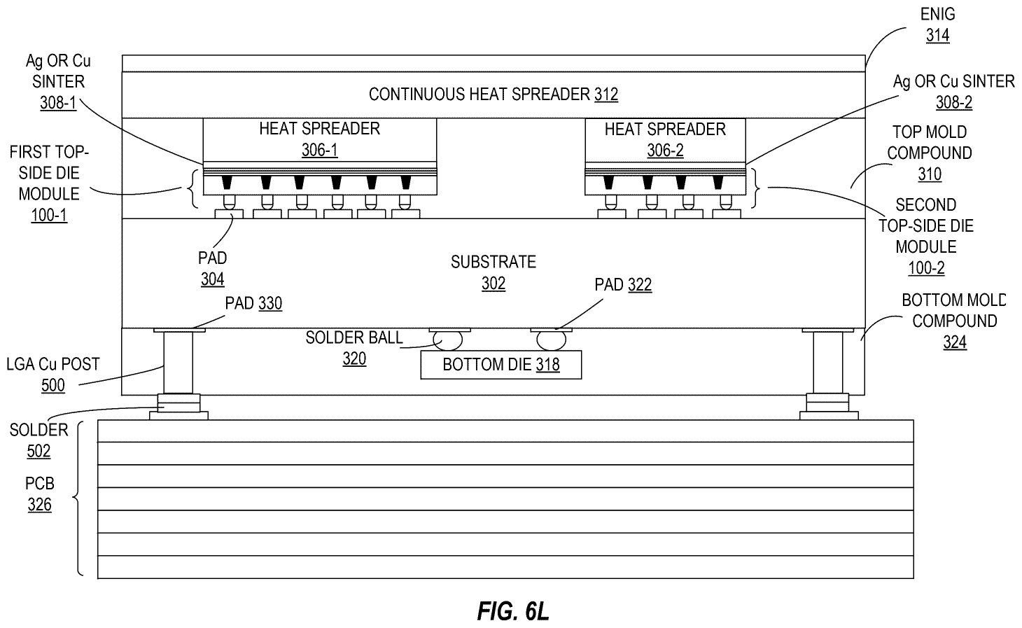

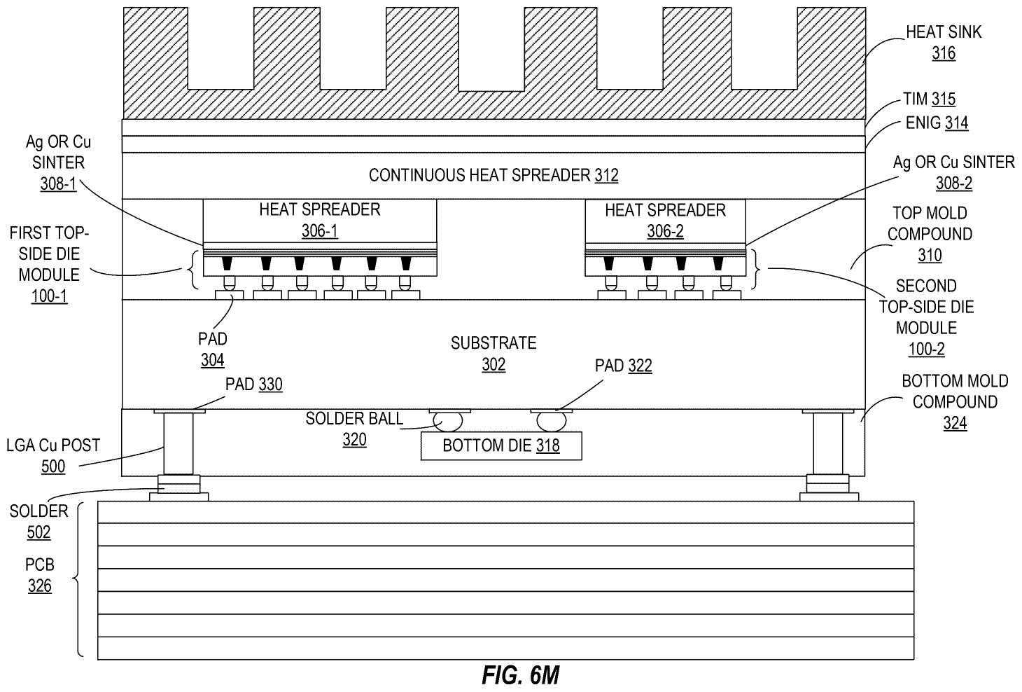

FIGS. 6A to 6M illustrate a procedure for fabricating the DSM package 300 of FIG. 5 and attaching the heat sink 316 and attaching the DSM package 300 to the PCB 326 as shown in FIG. 5, in accordance with one example embodiment of the present disclosure. It should be noted that not all steps of the procedure are required. Further, part of the procedure (e.g., the steps illustrated by FIGS. 6A to 6K) may be performed by one entity (e.g., a manufacturer of the DSM package 300) and other parts of the procedure (e.g., the steps illustrated by FIGS. 6L and 6M) may be performed by another entity (e.g., a customer that purchased the DSM package 300 from the manufacturer).

As illustrated in FIG. 6A, the process begins by attaching (electrically and mechanically) the bottom-side semiconductor die 318 to the bottom-side of the substrate 302 using, in this example, solder balls 320 and corresponding contact pads 322 on the bottom surface of the substrate 302. Compression molding and curing is performed to provide the bottom mold compound 324 that encapsulates the bottom-side semiconductor die 318, as illustrated in FIG. 6B.

Next, the module is flipped to perform the top-side assembly. The steps illustrated in FIGS. 6C to 6J are the same as that described above with respect to FIGS. 4A to 4E and FIGS. 4H to 4J. As such, those details are not repeated.

Then, bottom-side grinding is performed to expose the Cu posts 500, as illustrated in FIG. 6K. After exposing the Cu posts 500, the Cu posts 500 are ENIG plated, as also illustrated in FIG. 6K. The DSM package 300 is subsequently attached to the PCB 326 via the solder 502 and corresponding contact pads on the top surface of the PCB 326, and the heat sink 316 is attached on the top-side (or backside) of the continuous heat spreader 312 via TIM 315, as illustrated in FIGS. 6L and 6M.

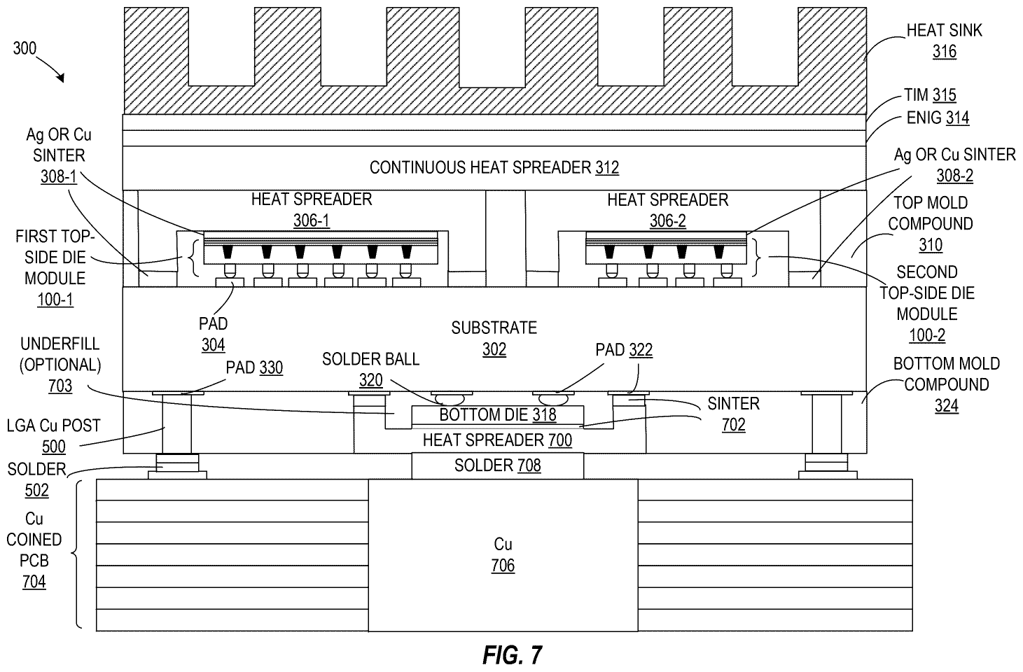

FIG. 7 illustrates another embodiment of the DSM package 300 that has both top-side cooling features and bottom-side cooling features. This embodiment is similar to that of FIG. 5 and as such the same reference numbers are used for like elements. However, in this embodiment, the top-side head spreaders 306-1 and 306-2 are over-sized (i.e., extend outward beyond the edges of the respective top dies 100-1 and 100-2, which provide improved heat spreading performance, and have legs that are mechanically attached to the surface of the substrate 302 so as to provide mechanical support. The DSM package 300 of FIG. 7 further includes a bottom-side heat spreader 700 attached to a bottom-side (or backside) of the bottom-side semiconductor die 318. The bottom-side heat spreader 700 may be formed of a thermally conductive material such as, e.g., SiC, Si, or Cu. The bottom-side heat spreader 700 is attached to the backside of the bottom-side semiconductor die 318 using a thermally conductive sintering material 702 (e.g., Ag or Cu sinter material). Note that, in this example, the bottom-side heat spreader 700 is over-sized (i.e., extends outward beyond the edges of the bottom die 318), which provides improved heat spreading performance, and has legs that are mechanically attached to the surface of the substrate 302 so as to provide mechanical support.

Optionally, an underfill material 703 may be applied as shown in FIG. 7. In other words, before applying the bottom mold compound 324, an underfill material 703 (e.g., a capillary underfill material) can be dispensed and cured to avoid an air pocket inside the heat spreader 700.

The DSM package 300 is attached (electrically and mechanically) to a top surface of a Cu coined PCB 704 (i.e., a PCB with a Cu region 706 extending from the top surface of the PCB to the bottom surface of the PCB for, in this case, heat transfer) by attaching the Cu posts 500 to the corresponding contact pads on the top surface of the Cu coined PCB 704 via the solder 502. In addition, the bottom-side heat spreader 700 is thermally and mechanically attached to the Cu region 706 of the Cu-coined PCB 704 via, in this example, solder 708.

In the example of FIG. 7, the bottom-side semiconductor die 318 can also include one or more high-power components.

In one embodiment, the substrate 302 arrives with the Cu posts 500 pre-attached to its bottom-side. To prevent damage to these pre-attached Cu posts 500, the bottom-side process is, in one embodiment, conducted first during component attachment.

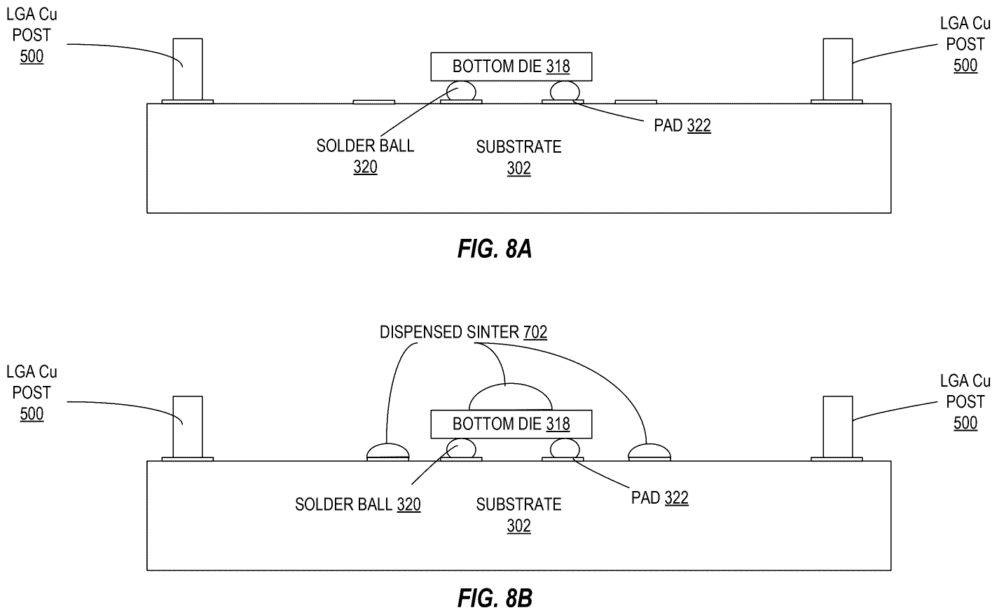

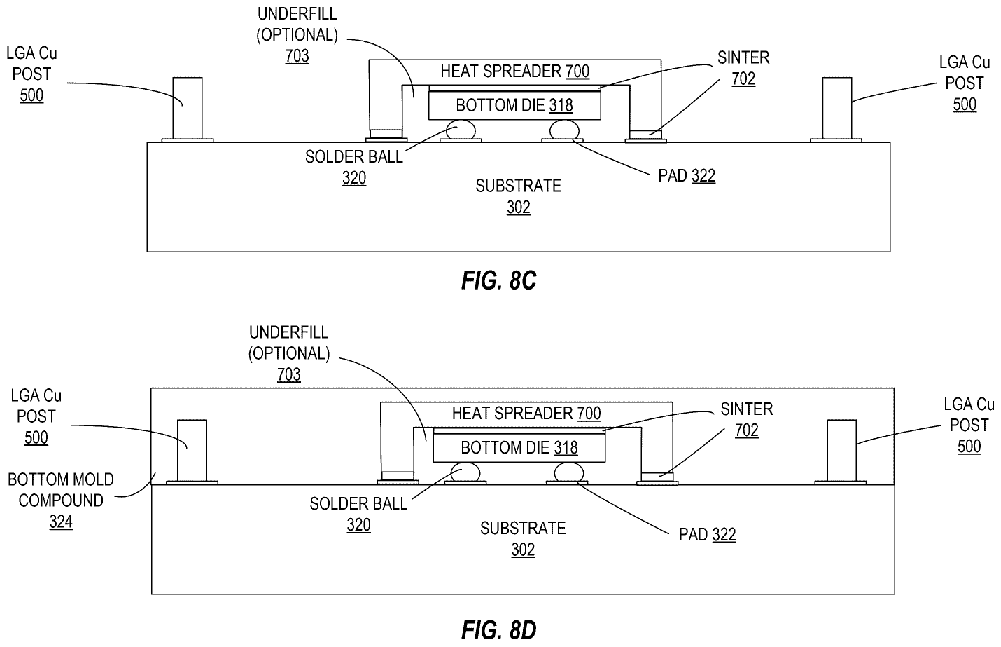

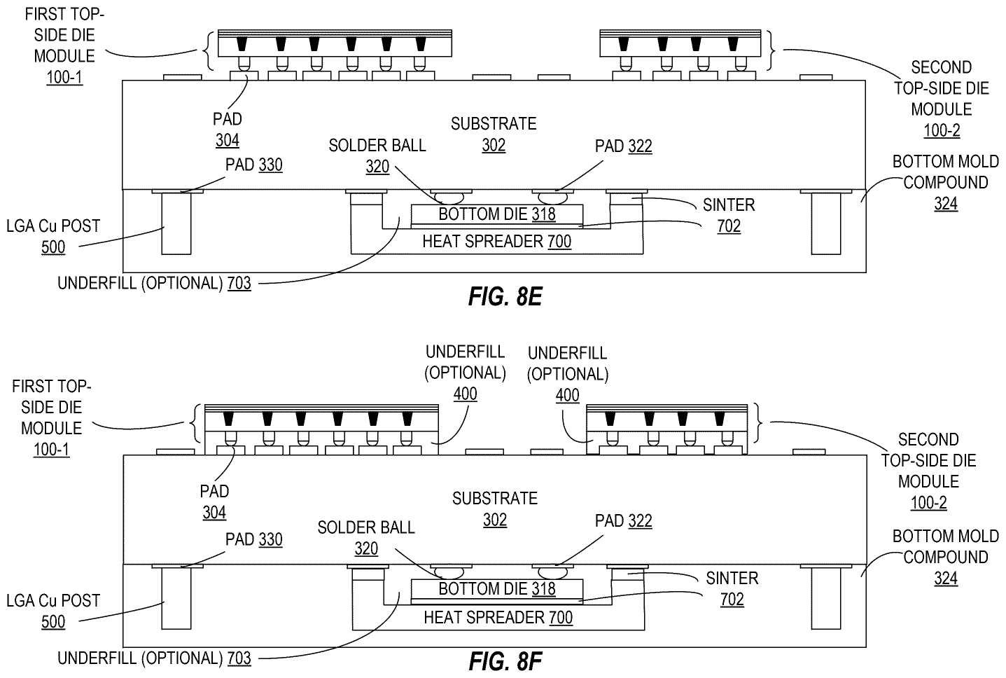

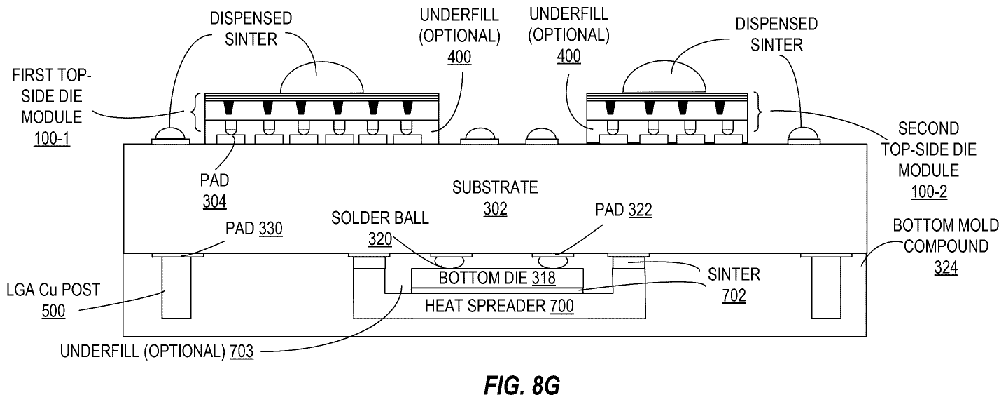

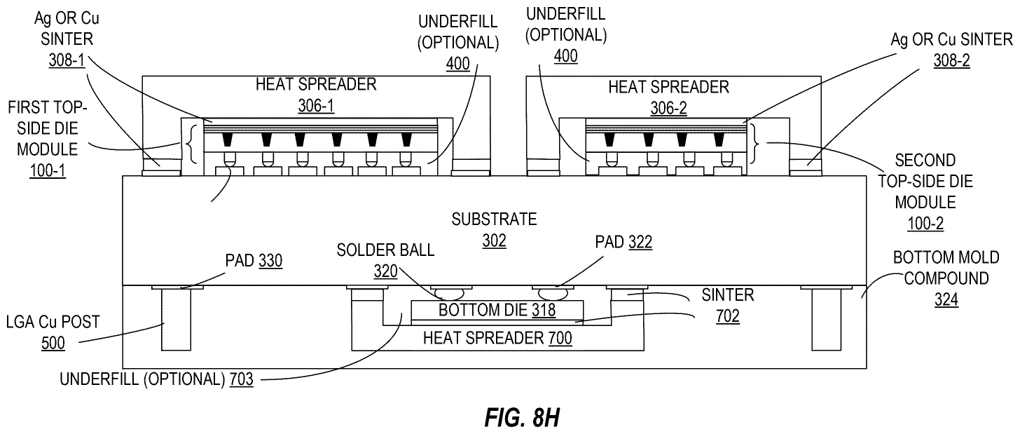

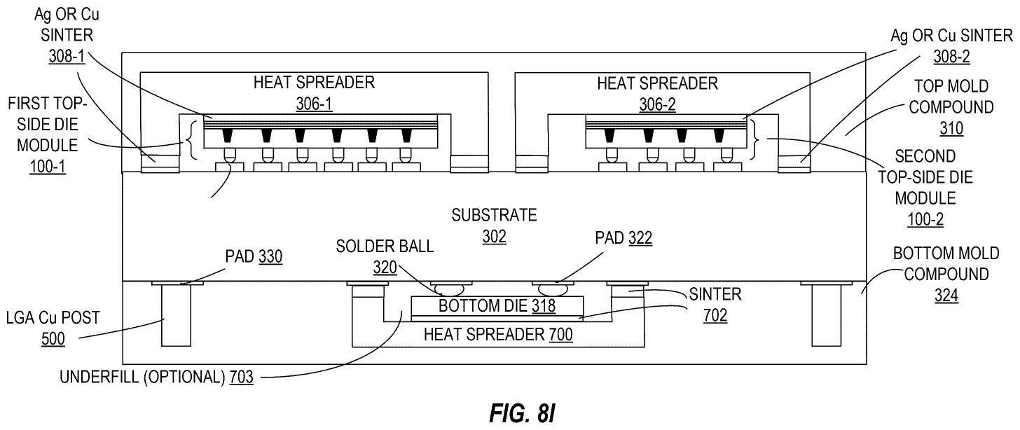

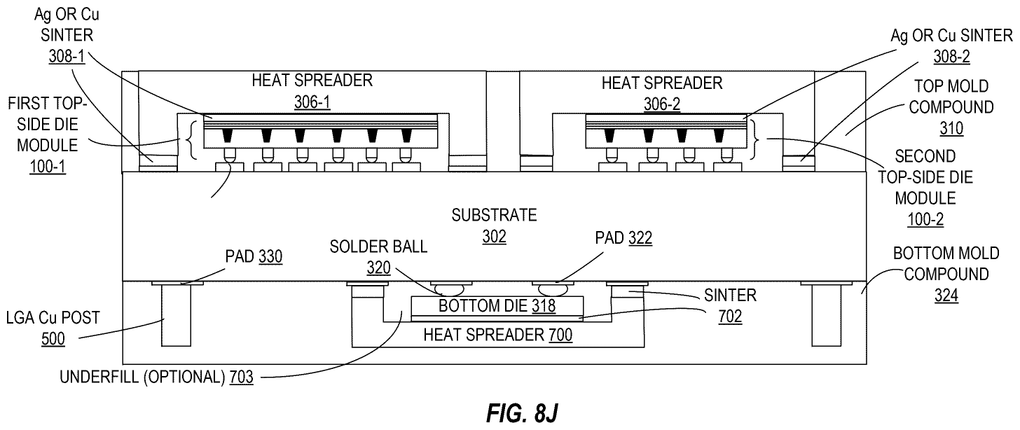

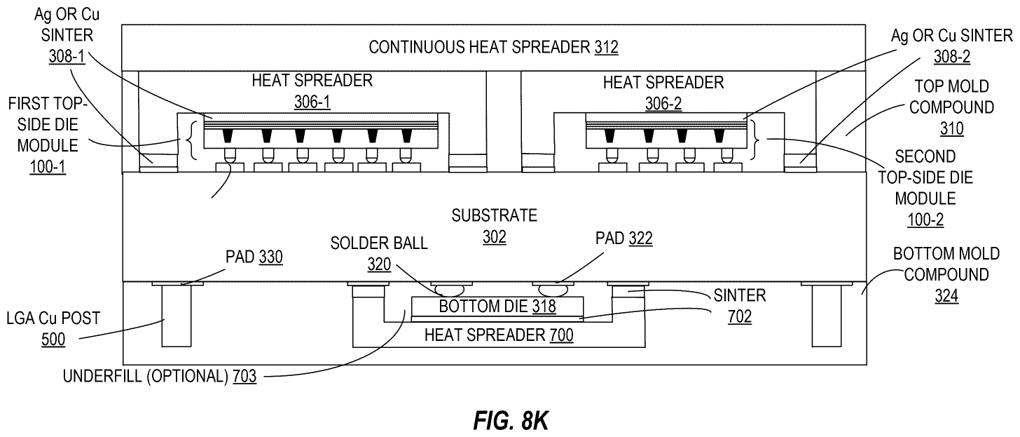

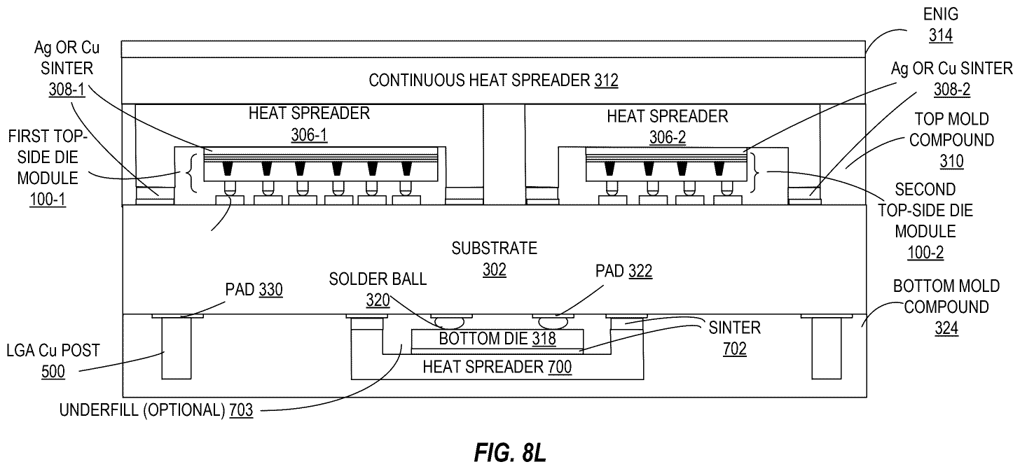

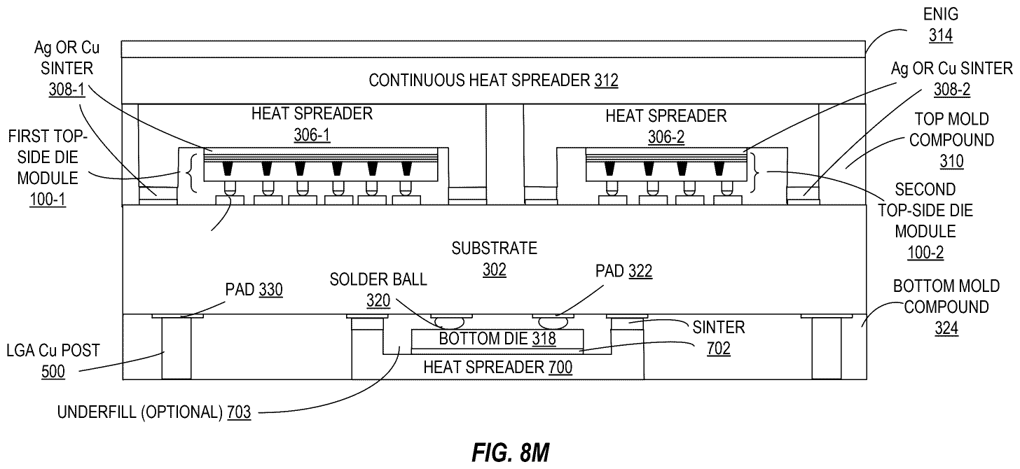

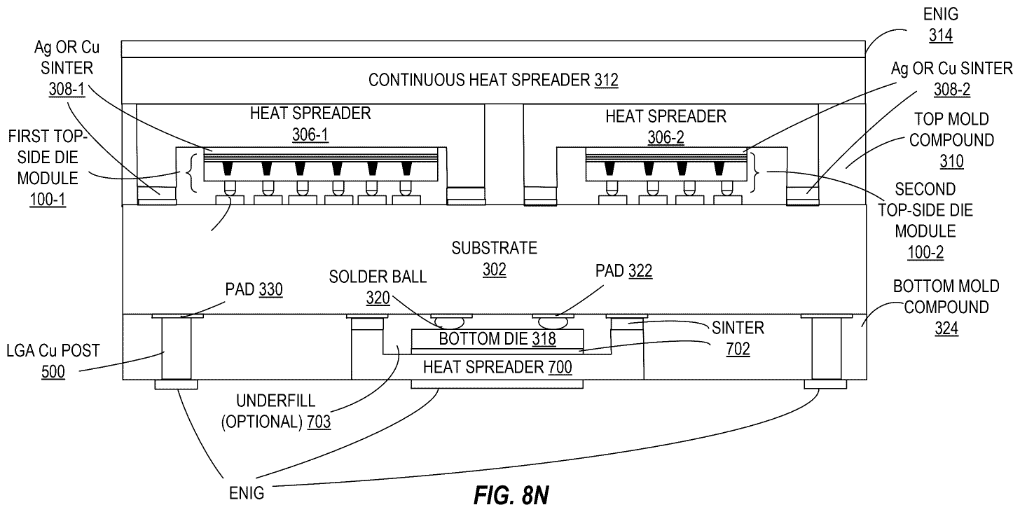

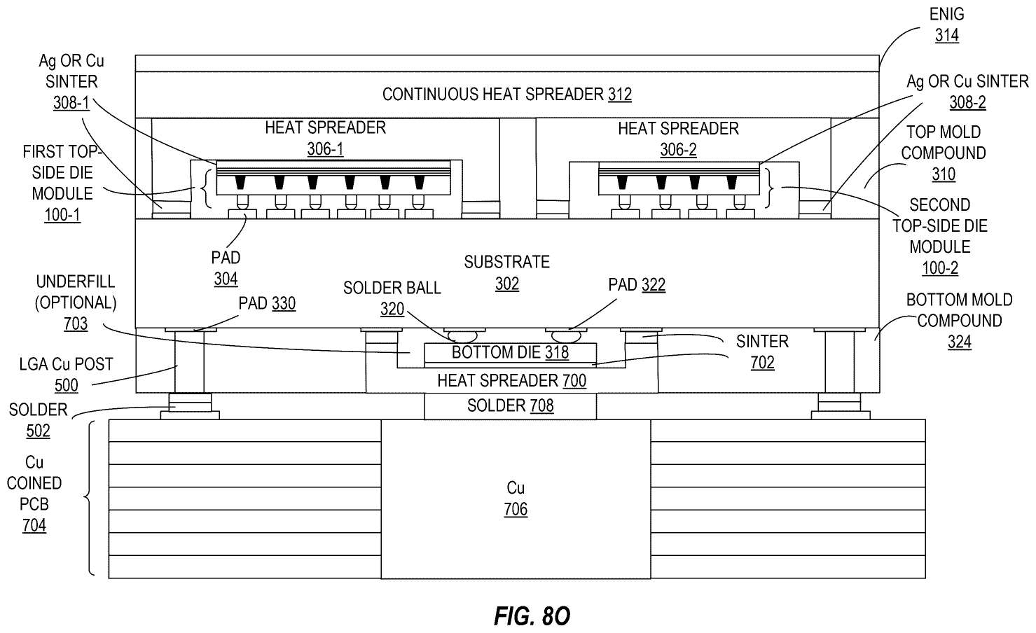

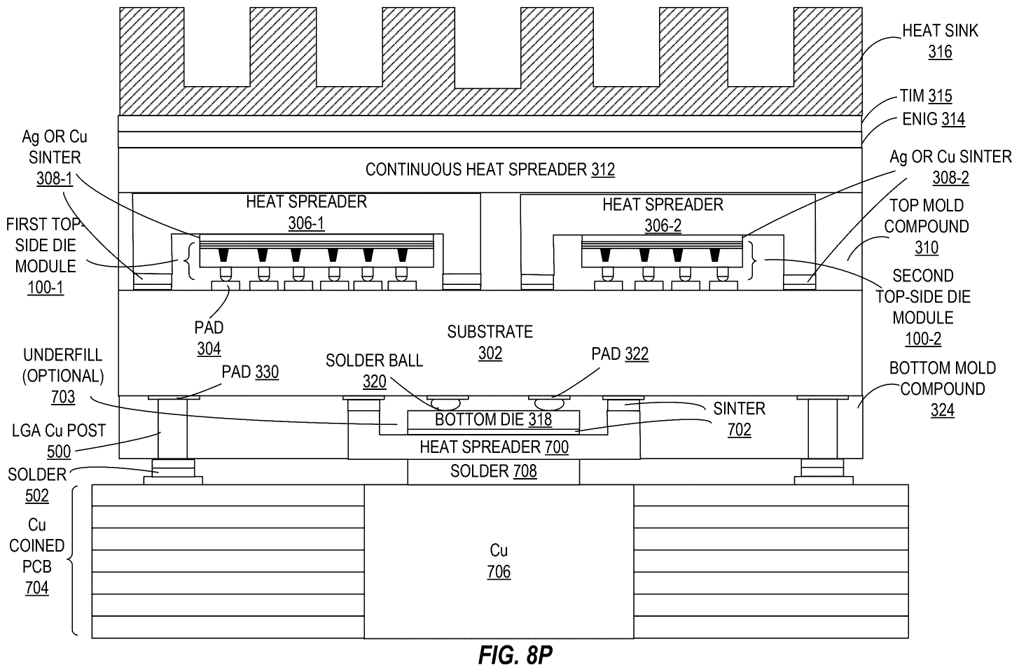

As illustrated in FIG. 8A, the bottom-side semiconductor die 318 is attached (electrically and mechanically) to the bottom-side of the substrate 302 through a series of steps including die pick, flux dipping, reflow, and cleaning. After completion of the bottom-side SMT attachment of the bottom-side semiconductor die 318, the sintering material 702 is dispensed on the top-side (i.e., the backside) of the bottom-side semiconductor die 318 as well as on contact pads for the legs of the bottom-side heat spreader 700, as illustrated in FIG. 8B. The bottom-side heat spreader 700 is placed on the back-side of the bottom-side semiconductor die 318 over the sinter material 702 and the module is then cured, as illustrated in FIG. 8C. Optionally, an underfill material 703 may be applied as shown in FIG. 8C. In other words, before applying the bottom mold compound 324, an underfill material 703 (e.g., a capillary underfill material) can be dispensed and cured to avoid an air pocket inside the heat spreader 700. Afterwards, the module undergoes bottom-side compression molding and cure, thereby providing the bottom mold compound 324 that encapsulates the bottom-side semiconductor die 318 and the bottom-side heat spreader 700, as illustrated in FIG. 8D.

Next, the module is flipped to perform the top-side assembly. The steps illustrated in FIGS. 8E to 8L are the same as that described above with respect to FIGS. 4A to 4E and FIGS. 4H to 4J. As such, those details are not repeated.

The module is then flipped, and the bottom-side co-grinding is performed to expose the bottom-side heat spreader 700 and Cu posts 500, as illustrated in FIG. 8M. Subsequently, the bottom-side then undergoes electroless nickel-immersion gold (ENIG) surface finish on the Cu post 500 and the bottom-side heat spreader 700, to thereby provide corresponding bottom surfaces which are compatible with any solder attached to Cu-coined PCB 704, as illustrated in FIG. 8N.

The DSM package 300 is then attached (e.g., by the customer) to the Cu-coined PCB 704 via solder 708 as illustrated in FIG. 8O, and the heat sink 316 is attached (e.g., by the customer) on the top-surface of the continuous heat spreader 312 via TIM 315, as illustrated in FIG. 8P. The continuous heat spreader 312 provides an efficient path for top-side cooling heat extraction using the heat sink 316, while the bottom-side heat extraction path directs heat from the backside of the bottom-side semiconductor die 318 to the bottom-side heat spreader 700 to the Cu region 706 of the Cu-coined PCB 704 to ambient. This enables additional bottom-side cooling through the bottom-side heat spreader 700 and coined PCB 704.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A double-sided molded (DSM) package comprising:
a substrate;
a first semiconductor die having a front side and a back side, the front side of the first semiconductor die electrically and mechanically attached to a top side of the substrate;
a top-side heat spreader on the back side of the first semiconductor die;
a top mold compound that encapsulates the first semiconductor die and the top-side heat spreader, wherein a back side surface of the top-side heat spreader is exposed through the top mold compound;
a continuous heat spreader on a top surface of the mold compound such that the continuous heat spreader is in thermal contact with the back-side surface of the top-side heat spreader exposed through the top mold compound; and
a second semiconductor die having a front side and a backside, the front side of the second semiconductor die electrically and mechanically attached to a bottom-side of the substrate.

2. The DSM package of claim 1, further comprising:
a third semiconductor die having a front side and a back side, the front side of the third semiconductor die electrically and mechanically attached to the top-side of the substrate;
a second top-side heat spreader on the back side of the third semiconductor die;
wherein:
the top mold compound further encapsulates the third semiconductor die and the second top-side heat spreader;
a back side surface of the second top-side heat spreader is exposed through the top mold compound; and
the continuous heat spreader is further in thermal contact with the back-side surface of the second top-side heat spreader exposed through the top mold compound.

3. The DSM package of claim 1, wherein the first semiconductor device is a Gallium Nitride (GaN) semiconductor die or a Gallium Arsenide (GaAs) semiconductor die.

4. The DSM package of claim 1, wherein the top-side heat spreader is formed of Silicon Carbide (SIC), Silicon (Si), or Copper (Cu).

5. The DSM package of claim 1, wherein the top-side heat spreader is formed of a material that is compatible with co-grinding.

6. The DSM package of claim 1, further comprising:
one or more metal layers on the back side of the first semiconductor die; and
a sinter material layer between the one or more metal layers on the back-side of the first semiconductor die and the front side of the top-side heat spreader.

7. The DSM package of claim 1, wherein the first semiconductor die comprises a plurality of vias that extend from the back side of the first semiconductor die towards the front side of the first semiconductor die, and the plurality of vias are filled with a thermally conductive material.

8. The DSM package of claim 7, wherein the thermally conductive material that fills the plurality of vias has a thermal conductivity in a range of an including 3 to 500 Watts per meter-Kelvin.

9. The DSM package of claim 1, further comprising a metallization layer on a backside surface of the continuous heat spreader that provides a surface that is compatible with a heat sink.

10. The DSM package of claim 1, further comprising a bottom-side heat spreader on the back side of the second semiconductor die.

11. The DSM package of claim 10, further comprising a bottom-side mold compound that encapsulates the second semiconductor die and the bottom-side heat spreader, wherein a back side surface of the bottom-side heat spreader is exposed through the bottom mold compound.

12. A method for fabricating a double-sided molded (DSM) package, the method comprising:
attaching a first semiconductor die to a top-side of a substrate, the first semiconductor die having a front side and a back side wherein the front-side of the first semiconductor die is electrically and mechanically attached to the top-side of the substrate;
attaching a top-side heat spreader on the back side of the first semiconductor die;
applying a top mold compound over the top surface of the substrate such that the top-side mold compound encapsulates the first semiconductor die and the top-side heat spreader;
performing top-side co-grinding such that a back side surface of the top-side heat spreader is exposed through the top mold compound;
forming a continuous heat spreader on a top surface of the mold compound such that the continuous heat spreader is in thermal contact with the back-side surface of the top-side heat spreader exposed through the top mold compound; and
attaching a second semiconductor die to a bottom-side of the substrate, the second semiconductor die having a front side and a backside wherein the front side of the second semiconductor die is electrically and mechanically attached to a bottom-side of the substrate.

13. The method of claim 12, wherein the first semiconductor device is a Gallium Nitride (GaN) semiconductor die or a Gallium Arsenide (GaAs) semiconductor die.

14. The method of claim 12, wherein the top-side heat spreader is formed of Silicon Carbide (SiC), Silicon (Si), or Copper (Cu).

15. The method of claim 12, wherein the top-side heat spreader is formed of a material that is compatible with the top-side co-grinding.

16. The method of claim 12, further comprising, prior to attaching the top-side heat spreader:
forming one or more metal layers on the back side of the first semiconductor die; and
dispensing a sinter material on a back side of the one or more metal layers;
wherein attaching the top-side heat spreader comprises placing the top-side heat spreader on the sinter material on the back-side of the one or more metal layers.

17. The method of claim 12, wherein the first semiconductor die comprises a plurality of vias that extend from the back side of the first semiconductor die towards the front side of the first semiconductor die, and the plurality of vias are filled with a thermally conductive material.

18. The method of claim 17, wherein the thermally conductive material that fills the plurality of vias has a thermal conductivity in a range of an including 3 to 500 Watts per meter-Kelvin.

19. The method of claim 12, further comprising applying a metallization layer on a backside surface of the continuous heat spreader that provides a surface that is compatible with a heat sink.

20. The method of claim 12, further comprising:
attaching a bottom-side heat spreader on the back side of the second semiconductor die;
applying a bottom-side mold compound on a bottom-side of the substrate such that the bottom-side mold compound encapsulates the second semiconductor die and the bottom-side heat spreader; and
performing bottom-side co-grinding such that a back side surface of the bottom-side heat spreader is exposed through the bottom mold compound.
